(19) United States
(12) Patent Application Publication
(10) Pub. No.: US 2026/0323888 A1
(43) Pub. Date: Oct. 15, 2026

(54) CONVERTER FOR A HEAT PUMP AND METHOD FOR PRODUCING A CONVERTER

(71) Applicant: Viessmann Holding International GmbH, Allendorf (Eder) (DE)

(72) Inventors: Artur WAGNER, Frankenberg (DE); Alexander SIMONOW, Frankenberg (DE); Yannick FEUSSNER, Burgwald (DE)

(21) Appl. No.: 19/690,167

(22) Filed: May 28, 2026

Related U.S. Application Data
(63) Continuation of application No. PCT/EP2024/080746, filed on Oct. 30, 2024.

(30) Foreign Application Priority Data
Dec. 13, 2023 (DE) 102023212633.8

(51) Int. Cl. H05K 7/20

(52) U.S. Cl. CPC H05K 7/209

(57) ABSTRACT

A method for producing a converter for a heat pump on an installation aid provides a converter having a heat sink, a housing with an upper part and a lower part, and electronics. The heat sink, the housing and the electronics are each moved to the installation aid one after the other in a common preferred direction and are assembled and joined together in the preferred direction on the installation aid. A converter for a heat pump is also provided.

### CROSS-REFERENCE TO RELATED APPLICATION

This application is a continuation, under 35 U.S.C. § 120, of copending International Patent Application PCT/EP 2024/080746, filed Oct. 30, 2024, which designated the United States; this application also claims the priority, under 35 U.S.C. § 119, of German Patent Application DE 10 2023 212 633.8, filed Dec. 13, 2023; the prior applications are herewith incorporated by reference in their entirety.

### FIELD AND BACKGROUND OF THE INVENTION

The invention relates to a method for producing a converter for a heat pump as well as to a converter for a heat pump. The converter has a heat sink, a housing, and electronics.

Heat pumps are increasingly employed to heat buildings. They have a refrigerant loop with a compressor. The compressor is in turn driven by an electric motor. In order to decrease wear as well as to increase efficiency, the electric motor is most commonly of a brushless configuration. Therefore, a converter is required to operate the electric motor. It usually has electronics through the use of which the functionality of the converter is provided. The electronics most commonly include power electronics with a bridge circuit adapted to the number of phases of the electric motor. Also, the electronics most commonly have an intermediate circuit capacity including one or more capacitors, such as electrolytic capacitors. In order to protect the electronics and to realize protection against accidental touch, the electronics are most commonly disposed in a housing. Also, this simplifies installation of the converter to further constituents of the heat pump as well as stock keeping.

Operating the converter creates electric losses predominantly in the region of the intermediate circuit capacity as well as the power electronics, leading to them heating up. In order to make operation of the converter possible over a comparatively long period of time without any disruption and with load decreased, cooling them is therefore required. For this purpose, most commonly the housing most commonly has multiple vent slots through which the heated air can exit. Furthermore, cooling is usually provided which includes a fan, for example. Through the use of this, (colder) ambient air is drawn into the interior of the housing so that the electronics present therein are subjected to an air flow. In the process, the electronics dissipate heat to the air flow which may exit the housing through the slots thereof. Alternatively or in combination, a (further) fan is provided through the use of which heated air is drawn from the interior of the housing into the environment. Feeding cold air into the housing takes place, for instance, through the use of the other fan or via the slots, if present. In order to improve a cooling effect, a heat sink is most commonly present which is usually made of a metal. The heat sink has a comparatively large surface area which is provided, for example, by multiple cooling fins. For instance, this involves the heat sink being disposed within the housing and in direct contact with the power electronics. Alternatively, the heat sink is fastened to an exterior of the housing so that in this way, the housing itself is cooled over a large surface. In other words, heat dissipation from the entire housing into the environment is thus improved.

For installation, the individual constituents of the converter are usually taken to an installation station and joined there. For instance, the housing is made of individual sheet metal plates which are installed to, such as hooked into, a cuboid metal frame. Initially, within the cuboid frame, the electronics are disposed as well as part of the sheet metal plates are installed, for instance. Following this, the fan is positioned in a suitable manner, most commonly on a side wall, and following this, the housing is closed by installing the remaining sheet metal plates. After closing, for instance, the heat sink is also installed on the bottom side of the housing.

Such a procedure provides a comparatively compact and robust converter. However, installation requires the frame to be pivoted multiple times to install the individual components. Therefore, that is usually done by hand, requiring a person to be trained. Thus, production costs and also production time are increased.

### SUMMARY OF THE INVENTION

It is accordingly an object of the invention to provide a particularly suitable converter for a heat pump and a particularly suitable method for producing a converter, which overcome the hereinafore-mentioned disadvantages of the heretofore-known devices and methods of this general type and with which production time and/or production costs are reduced, and expenditure and/or complexity are decreased.

With the foregoing and other objects in view there is provided, in accordance with the invention, a method for producing a converter for a heat pump on an installation aid, the converter having a heat sink, a housing with an upper part and a lower part, and electronics, wherein the heat sink, the housing, and the electronics are each moved to the installation aid one after the other in a common preferred direction and are assembled and joined together in the preferred direction on the installation aid.

With the objects of the invention in view, there is also provided a converter for a heat pump having a heat sink, a housing, and electronics, which are fastened to one another in a preferred direction only.

Advantageous further developments and configurations are the subject matter of the respective dependent claims.

The method serves to produce a converter for a heat pump. In particular, the heat pump serves to heat a building, for instance, a single-family home, a multi-family home, or a factory building. In particular, this involves the heat pump having a nominal thermal output of between 2.6 kW and 15 kW or of up to 60 kW. The converter is suitable, as well as provided and configured, to operate, that is, in particular to energize, an electric motor of the heat pump. For instance, this involves specifying, appropriately regulating, a speed and/or a torque of the electric motor by using the converter. In particular, a compressor is driven by the electric motor in turn. The compressor suitably serves to compress a refrigerant of a refrigerant loop of the heat pump. Alternatively or in combination, by using the, a further, or a second electric motor, a fan of the heat pump is driven through the use of which air is in particular blown or drawn across cooling fins or through a radiator network of the heat pump. The cooling fins/the radiator network is suitably a constituent of the refrigerant loop or at least thermally contacted with a constituent of the refrigerant loop.

The converter has electronics. The electronics suitably include a bridge circuit, in particular a B6 circuit. Preferentially, the converter includes a number of bridge branches. If the converter is of a three-phase configuration, three such bridge branches are present, in particular. In particular, each of the bridge branches has two semiconductor switches electrically connected in series, preferentially field-effect transistors, for instance MOSFETs, GTOs, or IGBTs. As far as the converter is single-phase, only one bridge branch or a single switch is present. For instance, the bridge circuit has a discrete structure, or the converter preferentially includes a power module through the use of which the bridge circuit is formed. For instance, the power module also has further structural parts.

Suitably, the converter, appropriately the electronics, has a connector unit for connecting the electric motor. The connector unit suitably has multiple individual connectors, wherein the number of the connectors appropriately corresponds to the number of the phases of the electric motor and/or the number of the bridge branches and preferentially equals them.

In particular, the converter, for example the electronics, has a supply connector. During operation, a direct voltage, for instance, is applied to the supply connector, for which purpose the supply connector is formed correspondingly. More preferably, however, an alternating voltage is applied there during operation, for instance a single-phase alternating voltage or a three-phase alternating voltage. For instance, the alternating voltage has an amplitude of 230V or 110V and/or a frequency of 50 Hz or 60 Hz. The supply connector is respectively suitable, in particular provided and configured, for this purpose. Appropriately, the converter, in particular the electronics, includes a rectifier which is configured as a diode rectifier, for example. It is suitably electrically connected to the bridge circuit, if present, via an intermediate circuit so that the converter is configured in the manner of a current converter.

The converter additionally includes a housing which in particular serves to protect the electronics. When in the installed state, the electronics are appropriately disposed within the housing and preferentially completely surrounded along their periphery by the housing. For instance, the housing is manufactured completely of a plastic, or at least individual constituents of the housing are made of the plastic. The housing has an upper part and a lower part. For instance, the housing also includes further constituents. More preferably, however, the housing is formed by the upper part and the lower part only. The upper part and the lower part are appropriately made of a plastic and preferentially injection-molded plastic parts.

For instance, this involves the upper part or the lower part being of a substantially flat configuration. More preferably, however, the lower part is configured in the manner of a tray so that the lower part has a circumferential edge and suitably a bottom. In other words, the lower part is of a substantially pot-shaped configuration. This facilitates arrangement of components therein. Also, this increases mechanical integrity of the lower part. Alternatively or more preferably in combination, the upper part is formed in the manner of a tray. Thus, it has an edge as well. Appropriately, the upper part thus has a bottom as well which, for instance, is flat or has one or more steps.

For instance, the upper part and the lower part are structurally identical to one another or appropriately different from one another. Thus, it is possible for the upper part and the lower part to be adapted to the respective arrangement and/or components they are respectively surrounded by when in the installed state so that an installation space needed is decreased. Suitably, when in the installed state, the respective edges of the upper part and the lower part abut one another so that the lower part is closed by the upper part. Thus, entrance of at least large foreign particles is avoided.

For instance, the upper part and/or the lower part are of a substantially continuous configuration. Alternatively, for example, one or more apertures/openings are present so that connection of the electronics located therein is enabled. More preferably, the upper part and/or the lower part includes a number of vent slots. Thus, air exchange is enabled, and consequently also removal of waste heat and/or excess heat from the housing into the environment.

Furthermore, the converter has a heat sink. The heat sink is suitably made of a metal, for instance, a copper or preferentially an aluminum. Thus, production costs and weight are reduced. In particular, the heat sink has multiple cooling fins so that a surface area is enlarged. Suitably, the converter is air-cooled, simplifying construction and production. Also, installation of the converter to further structural parts of the heat pump is simplified.

In the method, the converter is produced on an installation aid. The installation aid is a workpiece carrier which may suitably be used to produce multiple converters, in particular successively in time. In other words, the installation aid is reusable. In particular, this involves the installation aid including a bench or being formed thereby. Appropriately, this involves the bench being aligned substantially horizontally, which facilitates performing the method. The installation aid is appropriately static, which increases robustness and decreases production costs. Alternatively, it is possible, for instance, to traverse the installation aid and in particular displace it to different installation or population positions. More preferably, however, it is not possible for the installation aid to be pivoted in the process. In other words, it is only possible to displace the installation aid transversally which simplifies construction. The bench has rollers, for example, or they are fastened to the bench. Alternatively, the bench is hooked into an installation line. As the bench is not pivotable, construction is simplified and production costs of the installation aid are decreased. Also, the requirements concerning the location where the production takes place, in particular concerning the installation line, are decreased.

The method provides that the heat sink, the housing, and the electronics are each moved to the installation aid one after the other in a common preferred direction. In other words, the converter includes at least three components, namely the heat sink, the housing, and the electronics. Appropriately, the preferred direction is substantially vertical, appropriately vertically downwards. Thus, the heat sink, the housing, and the electronics are each initially positioned above the installation aid in a vertical direction, or the installation aid is placed below the heat sink, the housing, and the electronics one after the other in the vertical direction, and they are then each moved towards the installation aid. Suitably, they are laid down on the installation aid, for example, directly or indirectly via further structural parts/components.

For instance, the upper part and the lower part are moved to the installation aid together. Preferentially, they are moved there one after the other in time, for example, one directly after the other, or another one of the components is moved there between them, such as, for example, the electronics or the heat sink.

At the installation aid, appropriately on top of the installation aid, the heat sink, the housing, and the electronics are assembled. In particular, this involves the first one of the components which is moved to the installation aid to initially only be laid on top of the installation aid, and the next component which is moved to the installation aid in the preferred direction is suitably assembled on top of the component already located there. The component added thereafter in the preferred direction is appropriately disposed on top of one of the components already located there. For instance, the individual components are only disposed one on top of the other or at least partially introduced into one another. In particular, stacking of the individual components in the preferred direction one on top of the other thus takes place.

Additionally, the components are joined together at the installation aid, wherein this in particular takes place in the preferred direction. In other words, joining together, in particular fastening, takes place by applying a force in the preferred direction and/or movement of a corresponding fastening device in the preferred direction, each for instance only, mainly, or at least also.

For instance, the individual components are only joined together once all of the components have been moved to the installation aid. More preferably, however, joining together of the components each moved to the installation aid takes place at one of the components already located there before a further one of the components is moved there. Thus, stabilization of the same takes place which facilitates the consecutively added components being joined together.

Appropriately, the individual components are fastened to one another in the preferred direction only. At least, corresponding fastening is produced in this way only or predominantly. Appropriately, when performing the method, the installation aid is not rotated, and/or the preferred direction is perpendicular to the installation aid, in particular its extension. As far as the installation aid has the bench, the preferred direction is in particular perpendicular to the bench which is suitably disposed horizontally.

In the method, to produce the converter, only substantially only moving the individual components in the preferred direction is required. In other words, pivoting the partially made converter is not required, eliminating the need to shift or pivot the installation aid. Thus, complexity of the installation aid as well as further devices used to make the converter is reduced. Therefore, production costs and susceptibility to errors are reduced. Also, production time is decreased. Furthermore, this also decreases complexity when producing the converter, reducing errors. Consequently, rejects are decreased, and reworking is substantially not required. It is also possible for the method to be performed in an at least partially or completely automated manner, further reducing production costs.

For instance, the housing is initially moved to the installation aid and the heat sink is subsequently assembled thereon. More preferably, however, the heat sink is initially inserted into a receiver of the installation aid. Through the use of the receiver, stabilization and/or alignment of the heat sink appropriately takes place. The receiver is in particular formed at least partially by using a hole in the bench, if present, of the installation aid, which facilitates insertion. Also, complexity of the installation aid is decreased. In particular, after insertion, a form fit between the heat sink and the receiver is formed at least partially on an edge side. Suitably, the installation aid, for example the receiver, and/or the heat sink include an anti-rotation safeguard so that inserting the heat sink into the receiver is only enabled in one position. Thus, rejects are further decreased, and reworking of the converter is not required. Furthermore, performing the method is also enabled for an unskilled person.

Consecutively, the lower part is assembled on top of the heat sink and is attached thereto. Assembling the lower part onto the heat sink is in the preferred direction so that the lower part is located above the heat sink in the preferred direction. For instance, there is no mechanical contact between the lower part and the installation aid. In other words, the lower part and the installation aid remain spaced apart. Alternatively, the lower part rests on the installation aid and is stabilized in this way. Suitably, this involves the lower part having one or more protuberances which penetrate corresponding openings of the installation aid, in particular of the bench. Thus, the lower part is at least partially aligned. Appropriately, the protuberances are shaped such that, thereby, the converter can be installed to further constituents of the heat pump after being produced. In particular, at least one of the protuberances is thus shaped in the manner of a snap-fit or locking hook, wherein it is suitably not locked to the installation aid. Thus, removing the finished converter from the installation aid is facilitated, and two different functions are assumed by using the respective protuberance.

In particular, the lower part has a tray-like shape, and the heat sink is located at an exterior of the tray, preferentially of the bottom. For instance, this involves the bottom of the lower part being continuous so that the heat sink remains outside the housing. Alternatively, the lower part has a further opening which is closed by the heat sink and/or into which the heat sink is at least partially inserted so that part of the heat sink reaches inside the housing. The heat sink is at least guided through the lower part. Alternatively or in combination, for instance, the heat sink has one or more protuberances, such as domes, which in particular run in the preferred direction and which penetrate corresponding receivers of the lower part and thus partially project through, or in particular inside, the lower part.

Appropriately, the lower part is fastened, for example screwed, to the heat sink. Suitably, the screws are guided to the installation aid in the preferred direction and/or screwed into it in the preferred direction so that they run in the preferred direction. For example, the lower part is rigidly fastened to the heat sink so that their relative movement to one another is subsequently not possible. More preferably, however, even after fastening, at least little movement of the heat sink in relation to the lower part is enabled, wherein detachment is prevented, however. Thus, tolerance compensation is enabled in particular. Alternatively or in combination, in this way, oscillations of the heat sink are not, or only to a smaller extent, transmitted to the lower part during operation, as well as vice versa. In other words, the heat sink and the lower part are at least partially decoupled, decreasing operating noise. Alternatively, in a further operation of the method, a change in the fastening is made, wherein the heat sink is rigidly fastened to the lower part.

For example, directly after inserting the heat sink into the receiver, the lower part is assembled on top thereof. More preferably, however, before assembling the lower part on top of the heat sink, a fan receiver is initially inserted into a second receiver of the installation aid in the preferred direction. In other words, the fan receiver is moved in the preferred direction and in this way inserted into the second receiver of the installation aid. Due to this, the heat sink and the fan receiver are positioned next to one another perpendicular to the preferred direction. In other words, the two receivers are disposed next to one another so that, when the heat sink is inserted into the receiver and the fan receiver is inserted into the second receiver, the fan receiver and the heat sink are located next to one another.

For instance, the fan receiver and the heat sink are inserted into the respective receiver at the same time, or the fan receiver is correspondingly moved from the heat sink to the installation aid. More preferably, the heat sink is initially inserted, and the fan receiver is subsequently inserted. Suitably, the second receiver has an anti-rotation safeguard so that inserting the fan receiver into the second receiver is only enabled in a single position.

Once the fan receiver and the heat sink have been positioned, in particular, the lower part is assembled onto the fan receiver and the heat sink. Appropriately, the fan receiver and the heat sink are attached to the lower part so that robustness is increased. Alternatively, for instance, the fan receiver is only fastened to the heat sink.

The fan receiver serves to hold a fan and is suitable, in particular provided and configured, for this purpose. During operation, by using the fan, it is possible to generate an air flow along the heat sink which is suitably parallel to any cooling fins, if present, of the heat sink. For instance, air is drawn or, more preferably, blown through the heat sink by using the fan. In particular, the fan receiver is formed in such a way. Through the use of the fan receiver, for example, only a holder for the fan is formed which has a fan wheel driven by an electric motor. More preferably, however, the fan receiver furthermore includes a diffuser or the like through the use of which the air flow made by the fan is guided in a suitable manner, in particular towards or away from the heat sink. The diffuser is configured, for example, in the manner of a funnel and/or appropriately in direct mechanical contact with the heat sink so that a comparatively efficient air flow through the same can be generated. Preferentially, the fan receiver is a single piece and/or an injection-molded plastic part.

Appropriately, the fan receiver has an opening through which inserting a fan into the fan receiver is enabled. For instance, the opening is accessible from a side of the fan receiver facing away from the lower part. Alternatively, the opening is oriented in the direction of the lower part, that is, appropriately counter to the preferred direction. When assembling the lower part on top of the fan receiver, the opening remains clear, for example. More preferably, however, the opening is accessible from the lower part so that the opening of the fan receiver reaches into the lower part. For this purpose, the lower part has a corresponding recess which is in particular in alignment with the opening. Thus, access to the fan is also enabled from the lower part, at least after installing the lower part. As the opening reaches into the lower part, it is thus protected by the housing, avoiding any damage to the fan disposed therein after producing the converter.

For instance, the fan is already located in the fan receiver when the fan receiver is inserted into the second receiver, that is, before installing the lower part. More preferably, however, only following the lower part being disposed, the fan is inserted into the fan receiver in the preferred direction through the opening. Thus, pre-installation of the unit formed by the fan receiver and the fan is not required. Therefore, fewer operations are needed, and/or space requirements for producing the converter are decreased.

For instance, the fan is only loosely inserted into the fan receiver. More preferably, however, the fan is fastened there so that any unwanted detachment of the fan from the fan receiver is avoided. Also, their relative movement to one another is avoided so that noise load during operation is decreased. Preferentially, the fan is locked to the fan receiver. For this purpose, the fan receiver appropriately has one or more locking elements, preferentially locking tabs, which encompass the edge side of the fan when in the installed state. Due to this fastening, no additional tools and/or fastening devices are required to install the fan. Also, for installation, the fan is only moved in the preferred direction as well as a force is exerted onto it in the preferred direction. Therefore, automated manufacture is also enabled here.

Appropriately, this involves a device being present through the use of which the fan is ensured to be installed in a correct position. For example, the device is a constituent of the installation aid. Suitably, the device includes a camera through the use of which the fan partially introduced into the fan receiver undergoes optical verification. In particular, the fan has an optical marking, such as an adhesive label, through the use of which a draw side or a blow side is identified. Suitably, the device has a variable stop which is disposed in the fan receiver when the fan is inserted into the fan receiver. Through the use of the stop, introduction into the fan receiver is limited. For example, the stop is configured in the manner of a dome which projects though a corresponding auxiliary opening into the fan receiver. Once it has been verified/confirmed that the fan has been inserted into the fan receiver in the correct orientation, in particular, the stop is withdrawn, appropriately out of the complete fan receiver. Thus, further introducing of the fan into the fan receiver is enabled and the fan can be fastened in, appropriately locked to, the fan receiver.

Suitably, the electronics include a first printed circuit board. Appropriately, multiple electric and/or electronic structural parts are fastened to the first printed circuit board. Preferentially, they are at least partially electrically contacted with one another by the first printed circuit board, preferentially traces of the first printed circuit board, so that a circuit is formed. For example, the electronics are only formed by the first printed circuit board and the electric/electronic structural parts fastened thereto. Thus, complexity is decreased, and production is facilitated. More preferably, however, the electronics also include further constituents, increasing functionality.

The first printed circuit board is inserted into the lower part. This involves the first printed circuit board being moved at least also in the preferred direction so that the printed circuit board is inserted into, in particular penetrates, the lower part. After insertion, the first printed circuit board is appropriately surrounded along its periphery by the tray-like lower part.

For instance, the first printed circuit board is disposed in parallel to the preferred direction or suitably perpendicular to the preferred direction so that a comparatively flat converter is made. Preferentially, before insertion, the first printed circuit board is at least partially inclined in relation to the preferred direction, and it is at least partially pivoted during insertion, appropriately about an axis perpendicular to the preferred direction. This involves pivoting in particular by using a guide through the use of which the first printed circuit board is moved and/or aligned. In this way, when moving the first printed circuit board to the installation aid, large manufacturing tolerances can be chosen, wherein the first printed circuit board is aligned in a comparatively precise manner so that it is located in a comparatively precisely defined position. Appropriately, the lower part includes the guide so that a number of structural parts needed is decreased.

Appropriately, the power module, if present, is fastened to the first printed circuit board. Inserting the first printed circuit board into the lower part, which is appropriately formed in a tray-like manner, is suitably such that the power module abuts the heat sink. In particular, this involves the power module being located in front of the first printed circuit board in the preferred direction and thus on the side of the first printed circuit board facing the bottom of the lower part. In particular, the power module has one, for instance rudimentary, heat dissipator which is suitably manufactured of a metal. The heat dissipator preferably abuts the heat sink.

For instance, the power module abuts the heat sink directly or via a thermal interface medium, such as a thermal paste or a thermal pad. Thus, during operation, excess heat and/or waste heat is removed from the power module to the heat sink so that comparatively efficient cooling of the power module takes place. The heat sink is located at least partially outside the lower part/housing, and the lower part appropriately has a further opening or an aperture through which the thermal contacting of the power module with the heat sink takes place. Suitably, the heat sink rests at least partially inside the further opening, or the further opening is closed by the heat sink. As the power module abutting the heat sink is realized by inserting the first printed circuit board, readjusting or further operations are not required, further reducing production time and production costs. In summary, due to the abutment, the heat sink is preferentially thermally connected to the power module so that heat can be removed in particular by heat conduction. Preferentially, the abutment realizes direct heat conduction between the heat sink and the power module.

More preferably, all of the electric and/or electronic structural parts of the first printed circuit board are disposed on a same side. In other words, the printed circuit board is populated on one side only, which reduces production costs. Alternatively, it is populated on both sides so that it may be given a comparatively compact configuration. More preferably, all of the electric/electronic structural parts, with the exception of the power module, are disposed on one side. Thus, on the one hand, a printed circuit board which is substantially populated on one side can be used. On the other hand, the heat dissipated by the power module does not impair the other electric and/or electronic structural parts.

Preferentially, the fan receiver is present, and the fan is inserted therein before inserting the first printed circuit board. For instance, the fan is energized independently of the first printed circuit board. More preferably, however, it is energized by the first printed circuit board. Thus, a number of individual structural parts of the electronics is decreased. For instance, by inserting the first printed circuit board, electrical contacting of the fan with the first printed circuit board also takes place. For this purpose, on the side facing the fan, the first printed circuit board appropriately has a suitable contacting option. More preferably, however, after inserting the fan, a connector cable of the fan is connected to the first printed circuit board. Thus, the requirements concerning the fan are decreased, and a pre-existing fan can be used, for instance. Due to the limp configuration form of the connector cable, it is appropriately contacted with the printed circuit board from the side thereof opposing the heat sink. Thus, the first printed circuit board which is substantially populated on one side can be used. For example, this involves the opening not being covered by the first printed circuit board, which facilitates installation of the connector cable. More preferably, however, the opening is covered by the first printed circuit board so that the first printed circuit board can be given a comparatively large-area configuration. Also, entrance of foreign particles into the opening is avoided.

Appropriately, after inserting the fan, the connector cable is guided through the opening, and its end is moved laterally out of the lower part. Subsequently, the first printed circuit board is preferentially inserted, and subsequently, the end of the connector cable is contacted with the first printed circuit board, for which purpose corresponding plugs are in particular plugged into one another. Consequently, the connector cable runs about an edge of the first printed circuit board.

Preferentially, a capacitor, such as an electrolytic capacitor, which is associated with the intermediate circuit, if present, is fastened to the first printed circuit board. Preferentially, multiple such capacitors, preferentially four electrolytic capacitors, are fastened to the first printed circuit board. They are appropriately located on the side of the first printed circuit board opposing the power module so that the structural parts of the electronics which during operation of the converter have comparatively large heat development, namely the power module and the capacitors, are separated from one another by the first printed circuit board. In particular, the capacitors are offset perpendicular to the preferred direction in relation to the power module. In this way, thermal interaction thereof is decreased by the first printed circuit board.

For instance, the first printed circuit board is only loosely inserted into the lower part. More preferably, however, the first printed circuit board is attached to the lower part. For instance, this involves rigid fastening of the first printed circuit board to the lower part or, more preferably, at least partially floating support. In particular, for attaching, the first printed circuit board is locked to the lower part. In particular, a force is exerted onto the first printed circuit board in the preferred direction to make the lock. In particular, one or more locking hooks are formed integrally with the lower part, or the lower part at least has corresponding locking hooks which encompass an edge side of the first printed circuit board after attaching.

Preferentially, this involves the guide being present through the use of which the first printed circuit board is at least partially pivoted. Suitably, when inserting the first printed circuit board into the lower part, an edge of the first printed circuit board is moved along the guide, and the opposing edge of the first printed circuit board is locked to the lower part, wherein this is appropriately only done once the first printed circuit board has been pivoted completely. The guide in particular has one or more sliding fins along which the edge is moved. In particular, the sliding fin runs perpendicular to the preferred direction, at least in some portions. When inserting the first printed circuit board, the edge adjoins the sliding fins and is in particular moved perpendicular to the preferred direction thereby so that the first printed circuit board is pivoted. Suitably, the sliding fin has a rim through the use of which the edge is moved at least partially counter to the preferred direction so that comparatively rapid pivoting of the first printed circuit board takes place.

In particular, through the use of the sliding fin, the edge is moved into an undercut of the lower part included by the guide, for example, before pivoting the first printed circuit board is completed. In other words, during insertion in the preferred rotational direction, due to the pivoting, the first printed circuit board is introduced into the undercut of the guide. The undercut is appropriately substantially perpendicular to the preferred direction. Suitably, the edge of the first printed circuit board opposing the undercut is locked to the lower part, that is, encompassed in particular by the locking hooks, so that detaching the first printed circuit board from the lower part is prevented. In particular, this at least partially involves a floating support so that the first printed circuit board can be moved at least partially in its plane of extension. Appropriately, the guide includes one or more guiding fins which run at least partially in the preferred direction. For instance, they run oblique to the preferred direction or are radiused on their end sides. Through the use of the guiding fins, the printed circuit board is in particular guided laterally, appropriately to the sliding fin. Suitably, during insertion, the first printed circuit board slides between and along the guiding fins. Through the use thereof, the first printed circuit board is thus threaded into the desired position. In summary, the guiding fins act in the manner of a funnel. Thus, automated performing of the method is enabled, wherein manufacturing tolerances when inserting the first printed circuit board can be chosen to be comparatively large.

Attaching the first printed circuit board to the lower part, in particular the guide, which appropriately the guiding fin(s), which are suitably disposed in a funnel shape, and/or the sliding fin, through the use of which pivoting the first printed circuit board is elicited, wherein an edge of the first printed circuit board is preferentially moved into the undercut, and wherein the other edge is appropriately locked, is in particular independent of the method, in particular of installation in the preferred rotational direction only. Also, this is independent of use with a converter and is instead considered a standalone invention.

For instance, attaching the power module to the heat sink is only by placement or of the thermal paste, if present. More preferably, however, the power module is screwed to the heat sink. Suitably, the first printed circuit board has an installation opening through which an installation screw is guided in the preferred direction and is inserted into a screw receiver of the power module. In particular, the heat dissipator, if present, has the screw receiver. Appropriately, after fastening the installation screw, a head of the installation screw mechanically directly abuts the power module. Appropriately, the size of the installation opening is greater than the head of the installation screw, and when in the installed state, the installation screw is appropriately spaced apart from the installation opening. In other words, the installation opening only serves to deliver the installation screw so that the power module can be screwed to the heat sink thereby. Due to the installation opening, the required connecting device, namely the installation screw, can be delivered here as well so that installation can also be in the preferred direction, for example, from above.

Suitably, the first printed circuit board includes multiple such installation openings, preferentially two, and one installation screw each, by which the power module is screwed to the heat sink, is guided through each one of them. In particular, the power module has just as many screw openings as installation screws are used, and each screw receiver is appropriately associated with one of the installation screws. Thus, robustness is increased.

Due to such a configuration, in particular, the heat sink is rigidly connected to the power module and thus to the first printed circuit board. This involves the first printed circuit board appropriately being floatingly supported in the lower part so that little movement of the same in relation to the lower part is enabled. Also, the heat sink is appropriately only floatingly supported on the lower part. Suitably, the finished converter thus has the heat sink which is disposed at least partially or preferentially completely outside the housing and/or through the use of which the housing is closed at least partially. Also, the converter includes the first printed circuit board which is disposed within the housing and which is rigidly fastened to the heat sink, namely by the power module. Thereon, the first printed circuit board and the converter are supported in relation to the lower part, preferentially the complete housing, in a manner which is movable at least to a small extent, namely appropriately in a floating manner. Consequently, vibrations are only transmitted between the housing and the heat sink/first printed circuit board to a small extent. Now, if the heat sink is oscillated during operation due to cooling, this is transmitted to the first printed circuit board. From there, the vibrations are not, or only to a small extent, transmitted to the housing which is in particular fastened to further constituents of the heat pump when in the installed state, for example to a carrier. Due to this, acoustic and even mechanical load is decreased. The floating support of the heat sink and/or of the first printed circuit board, wherein the heat sink is rigidly fastened to the first printed circuit board, is independent of the method, in particular of installation of the individual components of the converter in the preferred direction only. Instead, this is considered a standalone invention.

In summary, when in the installed state, the first printed circuit board is more preferably firmly screwed to the heat sink. By contrast, the first printed circuit board is appropriately affixed to the lower part by clamped connections. Thus, in particular, no fixed connection is present between the housing and the first printed circuit board, which effects oscillation decoupling.

Preferentially, the heat sink includes one or more bolts projecting into the lower part through corresponding openings thereof, or they are at least fastened to the heat sink. This involves a clearance fit suitably being formed between the bolts and the respective opening so that at least slight movement is enabled. In particular, an end side of the first printed circuit board abuts the bolts and is thus at least partially stabilized. Alternatively or in combination, the first printed circuit board is screwed to the bolts, which increases stability. Preferentially, the first printed circuit board is electrically contacted with the bolts, preferentially by the screws. This in particular involves the bolt or the screw resting on a connector pad of the first printed circuit board through the use of which the heat sink is electrically connected to ground or to any other specified electric potential. Thus, safety or at least electromagnetic compatibility (EMC) is increased.

For instance, the installation aid has a groove or the like into which the lower part is inserted so that alignment takes place. More preferably, however, the lower part has a first centering opening which is assembled onto a first centering element of the installation aid. Through the use thereof, alignment of the lower part with the installation aid takes place so that consecutive installation is facilitated. Also, in this way, when delivering the lower part, that is, when moving in the preferred direction to the installation aid, larger manufacturing tolerances can be chosen. When the first centering opening has been assembled onto the centering element, in particular, a clearance fit is made between them. Thus, the force needed to assemble the lower part and also when consecutively removing it is decreased, with comparatively precise alignment of the lower part taking place nonetheless.

Appropriately, the first centering element is of a substantially conical, in particular frustoconical, configuration. Due to the conical shape, introducing the first centering element into the first centering opening is also possible with comparatively large tolerances, wherein comparatively precise alignment takes place through the use of further assembling on top. For instance, this involves the first centering element being in a single piece with further constituents of the installation aid, in particular the bench, if present. More preferably, however, the first centering element is variable or at least adjustable with respect to the further constituents of the installation aid, such as the bench. In this way, it is possible to adapt the installation aid to different charges or embodiments of the lower part so that corresponding alignment respectively takes place. Also, this may compensate for any war. The first centering element is appropriately made of a steel. Thus, it is possible for a comparatively large number of converters to be made through the use of the same installation aid.

Alternatively or more preferably in combination, the lower part has one or more protuberances which penetrate corresponding receivers of the installation aid when the lower part is moved to the installation aid. Thus, alignment of the lower part is simplified. Suitably, the protuberances are used for fastening during installation of the converter to further constituents of the heat pump.

Preferentially, the first printed circuit board has a second centering opening which is assembled onto a second centering element of the lower part. In particular, this involves the second centering element being fastened to, in particular formed integrally with, further constituents of the lower part, preferentially to a bottom, if present, if the lower part is of a tray-shaped configuration. In particular, this involves the second centering element facing away from the installation aid and/or being oriented counter to the preferred direction. A second centering opening of the first printed circuit board is assembled onto the second centering element. Appropriately, the second centering opening is provided by a hole, in particular a round hole, and the second centering element, for instance, is conical or has two small triangular or trapezoidal plates aligned counter to the preferred direction which are rotated 90° to one another about an axis parallel to the preferred direction so that a kind of cone is made. In other words, perpendicular to the preferred direction, the cross section of the second centering element is at least partially cross-shaped. Thus, comparatively precise alignment of the printed circuit board in relation to the lower part is also enabled here, wherein due to the configuration of the second centering element, only comparatively low material requirements are present. Appropriately, this involves the lower part being made in a single piece of a plastic. Due to such a configuration form of the second centering element, demolding is facilitated and there is no delay in cool-down either. As a result, is it possible for the second centering element to be manufactured with comparatively low manufacturing tolerances.

For instance, the two centering elements have any desired positioning relative to one another. More preferably, however, the first centering element and the second centering element are disposed on a common straight line which is parallel to the preferred direction. For instance, the two centering elements are in registry with one another or only disposed such that their projections onto one another in parallel to the preferred direction only partially overlap. Due to such an arrangement, the first printed circuit board is also aligned comparatively precisely in relation to the installation aid so that, during further operations of the method, the position of the first printed circuit board is comparatively precisely determined and known. Thus, for example, electrical contacting of individual regions of the first printed circuit board can take place in a safe and automated manner. In the process, it is possible for comparatively large manufacturing tolerances to be chosen for any other constituents of the lower part, in particular regarding fastening of the first printed circuit board to the lower part, for instance, the floating support, if present. In summary, due to the two centering elements, the first printed circuit board is aligned for installation. In particular, this involves this aspect, appropriately in conjunction with the guide and/or lock of the first printed circuit board to the lower part, being independent of any other method steps and being considered a standalone invention.

For instance, the housing is made with the lower part and the upper part, or they are installed to one another separately of the installation aid. Thus, when moving the lower part to the installation aid, the upper part is also moved to the installation aid. Appropriately, however, the lower part is initially disposed on the installation aid, and only consecutively in time is the upper part moved to the installation aid in the preferred direction. Thus, pre-installation is not required here either. For instance, this involves the upper part being assembled directly on top of the lower part, in particular after installing the first printed circuit board. For instance, the upper part is positioned directly on the lower part and, for example, directly fastened thereto so that the housing is in particular closed. More preferably, however, the upper part is positioned perpendicular to the preferred direction next to the lower part. Thus, the housing is still open so that further structural parts can also be installed.

More preferably, the upper part is attached to the lower part so that any detachment of the upper part from the lower part is avoided. Thus, consecutive operations of the method are facilitated. Preferentially, the upper part is tray-shaped, and the lower part is appropriately also tray-shaped, so that individual constituents of the converter can respectively be disposed therein, such as, for example, the first printed circuit board. For instance, to attach the upper part to the lower part, a hinge is used which is brought close in addition, for example. More preferably, however, the lower part and the upper part each have an edge-side hinge part which are fastened to one another so that a hinge is formed. Appropriately, the lower part and the upper part each include two such hinge parts so that two hinges are formed. This increases stability.

In order to fasten the two hinge parts to one another, for example, an installation device is used, such as a bolt. More preferably, however, one of the hinge parts is formed by a laterally opened sleeve or the like into which the other hinge part is introduced/hooked which is appropriately formed in the manner of a bolt. In summary, the two hinge parts are preferably hooked into one another. In particular, for fastening, the two hinge parts are pushed onto one another in the preferred direction. Thus, making the hinge only requires force to be applied in the preferred direction, decreasing requirements concerning tools used for this purpose. This may also be automated. Suitably, the hinge parts are at least partially locked so that detaching the two hinge parts from one another at least partially requires their deformation. Thus, any unwanted detachment is avoided, and robustness is therefore increased.

In order to close the housing, in particular, the upper part is pivoted onto the lower part by the hinge so that their edge sides abut one another, appropriately circumferentially. Suitably, the upper part is once again fastened to the lower part so that pivoting back is not possible. For fastening, snap-fit hooks are appropriately used, or the upper part and the lower part are locked to one another. Thus, automated manufacture is also possible here, and no additional tools are needed. For example, the upper part is of a flat configuration. More preferably, however, it has one or more protrusions/protuberances which are in particular adapted to the structural parts of the converter disposed in the housing. Preferentially, this involves a pot-shaped or box-shaped protrusion/protuberance being present within which the capacitors, if present, associated with the intermediate circuit are disposed and which are fastened to the first printed circuit board, for example. Preferentially, the upper part has multiple slots so that passage of air is enabled there so that cooling takes place here as well.

For instance, the upper part only serves to close the housing. More preferably, however, a second printed circuit board is inserted into the upper part in the preferred direction and is attached thereto. This involves the second printed circuit board being a constituent of the electronics. For example, the electronics are only formed by the second printed circuit board. More preferably, however, the first printed circuit board is present in addition, and the electronics thus include the first and second printed circuit boards. The are moved to the installation aid in parallel to one another, in particular at a time offset, and assembled onto the respectively associated structural part and joined.

For example, the second printed circuit board is screwed to the upper part, for which purpose in particular screws are used which are screwed-in in the preferred direction. More preferably, however, the upper part has a guide which is appropriately formed corresponding to the guide described above. By guiding the same, the second printed circuit board is locked to the upper part so that no additional fastening devices are required. Appropriately, an undercut is present into which an edge of the second printed circuit board is introduced. Preferentially, one or more guiding fins and/or one or more sliding fins are present through the use of which the second printed circuit board is pivoted. Suitably, the second printed circuit board is populated on one side only, preferentially on the side facing away from the installation aid. Thus, after fastening, the electric and/or electronic components fastened to the second printed circuit board are accessible, in particular plugs.

Preferentially, the first printed circuit board is present, and after attaching the second printed circuit board to the upper part, they are connected, preferentially by a cable. In particular, a flat cable is used for this purpose. Suitably, the flat cable is plugged into corresponding plugs fastened to the printed circuit boards. In particular, the plugs are offset in the direction of the hinge so that a distance thereof to the hinge is smaller than half the length of the respective printed circuit board. Preferentially, this involves the flat cable being guided across the edge of the upper part and the lower part having the hinge. In this way, on the one hand, material requirements of the flat cable are decreased. On the other hand, in this way, further constituents of the converter are not hindered by the flat cable when the upper part is folded onto the lower part. Once the second printed circuit board has been attached and preferentially electrically contacted with the first printed circuit board, in particular, the upper part is folded onto the lower part and thus the housing is closed.

In particular, the upper part has an opening through which electrical contacting of one or more connector points of the electronics, appropriately of the first printed circuit boards, is enabled. Thus, from outside the housing, in particular after installation is completed, electrical contacting of the electronics is enabled so that functional checks can take place. Preferentially, the first printed circuit board is aligned by the centering elements. Thus, automated verification is also enabled here. Preferentially, multiple connectors of the electronics are present, such as the supply connector and/or the connector unit. Alternatively or in combination, further connectors are present via which control can appropriately take place. They are suitably disposed in corresponding openings of the housing, and they are appropriately electrically contacted as well during the functional checks.

The converter is suitable, in particular provided and configured, to form a constituent of a heat pump. This involves the converter appropriately serving to energize an electric motor through the use of which a compressor of a refrigerant loop is driven, in particular. The converter has a heat sink, a housing, and electronics. This appropriately involves the electronics being disposed within the housing so that they are protected by the housing.

The heat sink is preferentially disposed at least partially at an exterior of the housing and suitably penetrates an opening of the housing. In particular, the electronics are thermally contacted with the heat sink, appropriately directly, so that heat removal is improved. In particular, the housing has an upper part and a lower part which are joined together, however, appropriately not in a single piece with one another. This involves the heat sink, the housing, and the electronics, preferentially all of the structural parts or components of the converter, being fastened to one another in a preferred direction only. In other words, fastened of the same to one another is in a preferred direction only. However, movement of the components perpendicular to the preferred direction is prevented/inhibited or at least limited due to any other circumstances. Thus, producing the converter does not require any tilting of the partially installed converter, and they can be assembled in the preferred direction only. Thus, automated production of the converter is enabled or at least facilitated.

Alternatively or in combination with fastening in the preferred direction only, for instance, the heat sink is rigidly fastened to the electronics, and this assembly is appropriately floatingly supported on the housing. The heat sink suitably projects out of the housing and is thus disposed at least partially or completely outside the housing, whereas the electronics are located within the housing, for instance partially or preferentially completely. Consequently, during operation, relatively great oscillations of the housing (for example, due to attachment of the housing to a compressor, fan, etc., of the heat pump, if present) are not, or only to a small extent, transmitted to the heat sink and the electronics. Consequently, oscillation load of the electronics is decreased. Also, for example, oscillations of the heat sink are not, or only to a small extent, transmitted to the housing, as well as vice versa. Consequently, noise load is decreased.

Alternatively or in combination with supporting or fastening in the preferred direction only, the converter, preferentially the housing, has a guide through the use of which a printed circuit board of the electronics, preferentially the first or second printed circuit boards, if present, are guided during installation so that they are located in a predetermined position. The guide in particular has an undercut, wherein a guiding fin and/or a sliding fin are appropriately disposed such that an edge of the printed circuit board is guided into the undercut as it is moved in the preferred direction. The sliding fin is in particular located below the respective printed circuit board in the preferred direction, and through the use thereof, the edge of the printed circuit board is preferentially at least partially lifted counter to the preferred direction and is introduced into the undercut. By contrast, during installation, the printed circuit board, as it is moved in the preferred direction, initially comes into contact with the guiding fin which is suitably disposed in particular above the undercut in the preferred direction. Through the use thereof, the (respective) printed circuit board is aligned perpendicular to the preferred direction in a centered manner. Suitably, the guide furthermore has a locking connection through the use of which the edge of the printed circuit board opposing the undercut is locked. Thus, to attach the (respective) printed circuit board to the housing part, such as the lower part and/or the upper part, no additional fastening device is required, and by moving the printed circuit board in relation to the housing in the preferred direction, attachment takes place, wherein the printed circuit board is pivoted in a suitable manner. Appropriately, the guide includes a centering element through the use of which the printed circuit board is furthermore aligned. The printed circuit board includes a centering opening for this purpose. Suitably, the centering element is associated with the edge of the printed circuit board which is being locked. Thus, it is ensured that the locking actually takes place, wherein larger tolerances can be chosen when bringing the printed circuit board close.

As far as a structural part is referred to as a first, second, . . . structural part, this only refers to a certain structural part. In particular, this does not mean that a corresponding number of such structural parts is present.

The invention additionally relates to a heat pump with such a converter. The further developments and advantages explained in conjunction with the method are to be applied mutatis mutandis to the converter/the housing/the guide/the support/the heat pump as well as among each other, and vice versa.

Other features which are considered as characteristic for the invention are set forth in the appended claims.

Although the invention is illustrated and described herein as embodied in a converter for a heat pump and a method for producing a converter, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE FIGURES

FIG. 1 is a schematic block diagram of a heat pump having a converter;

FIGS. 2 and 3 are respective diagrammatic, perspective and sectional views of the converter having a housing with an upper part and a lower part;

FIG. 4 is a flow chart of a method for producing the converter;

FIGS. 5 and 6 are different perspective views of an installation aid for producing the converter;

FIGS. 7 and 8 are different perspective views of the converter in a first production stage;

FIGS. 9 and 10 are fragmentary, perspective views of a guide of the lower part;

FIG. 11 is a top view of the converter in a second production stage, wherein a first printed circuit board is inserted into the lower part;

FIG. 12 is a perspective view of the upper part having a second printed circuit board inserted therein;

FIGS. 13 and 14 are fragmentary, perspective views of a guide of the upper part;

FIG. 15 is a perspective view of the upper part and the lower part resting on the installation aid; and

FIG. 16 is a perspective view of the finished converter resting on the installation aid.

### DETAILED DESCRIPTION OF THE INVENTION

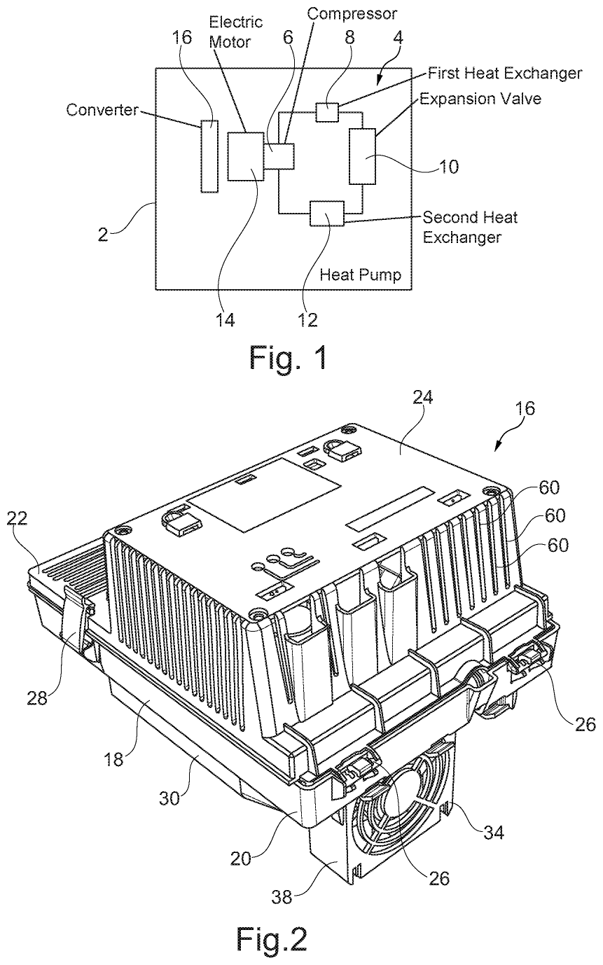

Referring now in detail to the figures of the drawings, in which parts corresponding to one another are provided with the same reference symbols, and first, particularly, to FIG. 1 thereof, there is seen a schematic, simplified view of a heat pump 2 which serves to heat a building. The heat pump 2 has a refrigerant loop 4 which includes a compressor 6. Through the use of the compressor 6, during operation, a gaseous refrigerant is compressed. As a result, the refrigerant is heated. It is guided to a first heat exchanger 8 which is thermally coupled to further constituents of a heater when in the installed state. Via the first heat exchanger 8, thermal energy is extracted from the refrigerant loop of the heat pump 2. As a result, the refrigerant cools down, wherein it transitions to the liquid phase. Subsequently, the refrigerant is directed to an expansion valve 10 through the use of which the pressure is lowered, wherein part of the liquid refrigerant is vaporized. As a result, it also cools down to a comparatively strong degree. The cooled down refrigerant is guided to a second heat exchanger 12 which, depending on the configuration of the heat pump 2, is subjected to ambient air or a liquid medium. There, energy is accepted by the refrigerant, leading to vaporization of the refrigerant, which is subsequently guided to the compressor 6 again so that the refrigerant loop 4 is completed.

The compressor 6 is driven by an electric motor 14 which is configured as a brushless DC motor (BLDC). In a variation not depicted in more detail, the electric motor 14 is of a different configuration and is a brushed commutator motor, for instance. In order to energize the electric motor 14, a converter 16 is employed which is electrically connected to a supply grid through the use of which electric alternating current is carried, in particular.

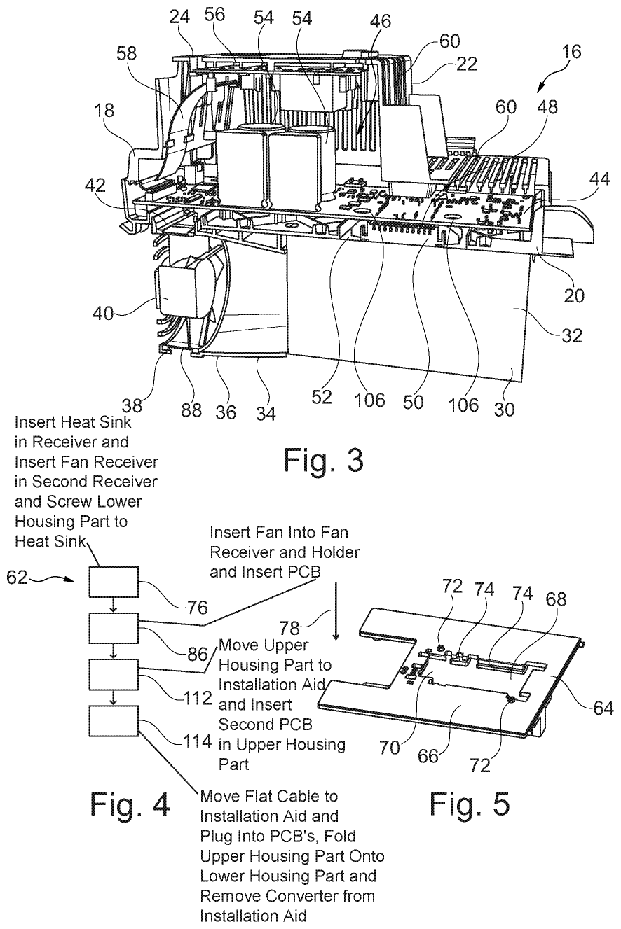

FIG. 2 is a perspective view and FIG. 3 is a sectional view of the converter 16. The converter 16 has a housing 18 having a lower part 20 and an upper part 22 which are manufactured of a plastic by injection molding. The lower part 20 and the upper part 22 are each tray-shaped, wherein their openings are directed towards one other, and wherein their edges abut one another. The upper part 22 furthermore has a box-shaped protuberance 24 which is directed away from the lower part 20 so that the bottom of the upper part 22, that is, the wall facing away from the lower part 20, does not have a planar but a step-shaped form.

Through the use of two hinges 26, the upper part 22 is pivotally supported on the lower part 20. This involves preventing any uncontrolled pivoting by two snap-fit hooks 28 through the use of which the upper part 22 and the lower part 20 are locked and which are located in a region of the housing 18 spaced apart from the hinges 26.

On the side facing away from the upper part 22, a heat sink 30 is fastened to the lower part 20, is manufactured of an aluminum and has multiple cooling fins 32 disposed in parallel to one another. The cooling fins 32 face away from the lower part 20 and are oriented perpendicular thereto. Also fastened to the lower part 20 is a fan receiver 34 which has a diffuser 36 and a holder 38 and is made of a plastic. Through the use of the diffuser 36, the heat sink 30 and the holder 38 are fluidically connected. Held in the holder 38 is a fan 40 which is disposed perpendicular to the cooling fins 32 and perpendicular to the bottom of the lower part 20. The holder 38 has an opening 42 which reaches into the lower part 20 so that it is accessible from within the housing 18.

A first printed circuit board 44 of electronics 46 is disposed within the housing 18. The first printed circuit board 40 is disposed in parallel to the bottom of the lower part 20, and thereon, on the side facing the bottom, a power module 48 is fastened which includes multiple power semiconductor switches not depicted in more detail by which a bridge circuit is formed. Furthermore, the power module 48 includes a heat dissipator 50 which is manufactured of an aluminum, wherein the power semiconductor switches are located between the heat dissipator 50 and the first printed circuit board 44.

In the region of the power module 48, the lower part 20 has a further opening 52 which is covered completely and thus closed by the heat sink 30. The heat dissipator 50 is located in the further opening 52 and mechanically abuts the heat sink 30 directly or via a thermal paste not depicted in more detail so that they are thermally contacted with one another.

On the one side of the first printed circuit board 44, only the power module 48 is located, and the first printed circuit board 44 is otherwise populated on the opposing side. There are also four (electric) capacitors 54 on the first printed circuit board 44 which are not in registry with the power module 48 but disposed at a lateral offset in relation thereto. The capacitors 54 are surrounded within the protuberance 24. A second printed circuit board 56 of the electronics 46, which is disposed in parallel to the first printed circuit board 44, is attached to the interior of the protuberance 24, namely to its bottom.

The first printed circuit board 44 and the second printed circuit board 56 are signal connected as well as electrically connected by a flat cable 58. The flat cable 58 is guided along the interior of the upper part 22 facing the hinges 26. Furthermore, multiple slots 60 are incorporated in the upper part 22 through which air can enter and exit the housing 18.

During operation of the converter 16, an electric voltage required to operate the electric motor 14 is provided by the power module 48. As a result, the power semiconductor switches, from which the waste heat is dissipated to the heat dissipator 50, heat up. From there, the heat is transmitted to the heat sink 30 so that it is heated up. During operation of the fan 40, an air flow through the diffuser 36 is made which is directed along the cooling fins 32 so that the excess heat is dissipated to the ambient air and the heat sink 30 is cooled.

Supply of the power module 48 is by an intermediate circuit having the capacitors 54. Through the use thereof, the electric voltage of the intermediate circuit is stabilized. The waste heat created in the process as well as due to any other operation of the electronics 46, by contrast, is dissipated to the environment via the slots 60.

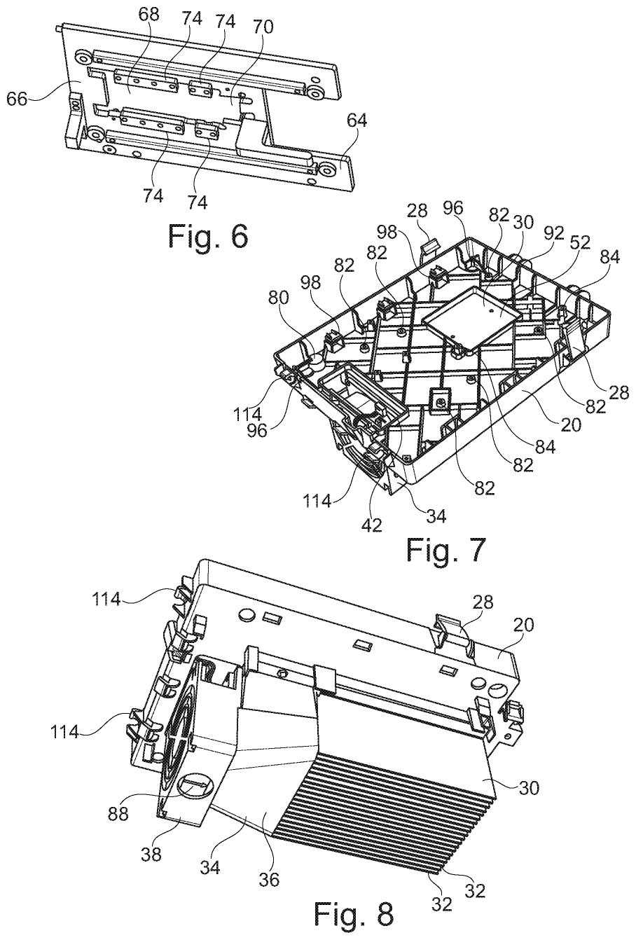

FIG. 4 shows a method 62 for producing the converter 16. The method 62 is performed in an at least partially or completely automated manner, for which purpose an installation aid 64 is used which is shown in a top perspective view in FIG. 5 and in a bottom perspective view in FIG. 6. The installation aid 64 which forms a workpiece carrier, in particular, has a substantially planar bench 66 into which a receiver 68 is introduced which transitions into a second receiver 70. Two first centering elements 72 are adjustably fastened on the top side of the bench 66. The first centering elements 72 are structurally identical to one another and are provided by a truncated cone made of stainless steel. The two first centering elements 72 are associated with opposing corners of the assembly formed of the two receivers 68, 70 and the overhang over the top side of the bench 66 is variable by adjustment.

On the bottom side, four installation rails 74 are fastened to the bench 66, wherein each receiver 68, 70 is associated with one of the installation rails 74 on opposing sides. The installation rails 74 associated with the same receiver 68, 70 project inside the respective receiver 68, 70 at different depths.

In the method 62, in a first operation 76, the heat sink 30 is inserted into the receiver 68, and the fan receiver 34 is inserted into the second receiver 70. For insertion, the heat sink 30 as well as the fan receiver 34 are moved to the installation aid 64 in a preferred direction 78 and are inserted into the corresponding receiver 68, 70. The preferred direction 78 runs perpendicular to the extension of the bench 66, and the first centering elements 72, namely the axis of the respective truncated cone, is parallel to the preferred direction 78.

The shape of the receiver 68 is adapted to the heat sink 30, and the shape of the second receiver 70 is adapted to the fan receiver 34, in particular to the diffuser 46. Due to the installation rails 74 and their overhang into the respective receiver 68, 70, inserting the heat sink 30 and the fan receiver 34 is enabled in a single orientation only. As a result, the diffusor 36 subsequently abuts an edge side of the heat sink 30. The fan receiver is disposed perpendicular to the preferred direction 78 next to the heat sink 30. The receiver 68 thus in particular forms a “heat sink receiver,” and the second receiver 70 in particular forms a “diffuser receiver.”

Consecutively, the lower part 20 is moved to the installation aid 64 in the preferred direction 78 and is laid on top thereof on an edge side. Due to the configurations of the receivers 68, 70, the lower part 20 is also assembled onto the heat sink 30 and the fan receiver 34. The first centering elements 72 each penetrate a correspondingly shaped first centering opening 80 of the lower part 20 which is of a blind hole-type configuration, wherein the shape of the blind hole is frustoconical. Thus, a clearance fit between the first centering elements 72 as well as the first centering openings 80 is realized, and the lower part 20 is consequently aligned. As a result, it is ensured that the opening 42 of the fan receiver 34 reaches inside the lower part 20 and that the further opening 52 of the lower part 20 is closed by the heat sink 30, as shown in FIG. 7 as a perspective view from the side facing away from the bench 66. The installation rails 74 and the first centering elements 72 are preferentially elements for centering the diffuser 46 and the heat sink 30 according to “poka yoke.” Through the use thereof, pre-alignment for the diffuser 46 and the heat sink 30 suitably takes place in order that receiving in the lower part 20 succeeds.

Furthermore, in the first operation 76, multiple screws 82 are moved into the lower part 20 in the preferred direction 78 through the use of which screws the lower part 20 is screwed to the heat sink 30 as well as to the fan receiver 34. This involves the holes of the lower part 20 through which the screws 20 are guided to be comparatively large so that floating support of the heat sink 30 as well as of the fan receiver 34 on the lower part 20 is realized. Also, in the preferred direction 78, two bolts 84 of the heat sink 30 are guided through corresponding apertures of the lower part 20 in the preferred direction 78 and are screwed to the other constituents of the heat sink 30 so that the heat sink 30 projects inside the lower part 20. As a result, the converter 16 shown in a top perspective view in FIG. 7 and in a bottom perspective view in FIG. 8 has a first production stage, wherein up until then, the individual constituents of the converter 16 have only been moved to the installation aid 64 in the preferred direction 78 and there have been assembled in the preferred direction 78 and joined together.

In a subsequent second operation 86, the fan 40 is inserted into the fan receiver 34, namely into the holder 38, in the preferred direction 78 through the opening 42, namely up until a variable stop which is located in the holder 38. The variable stop is formed by a dome, not depicted in more detail, of the installation aid 64 which is introduced into the holder 38 through an auxiliary opening 88 thereof from the side facing away from the bench 66 and is parallel to the preferred direction 78. Due to the dome, complete introduction of the fan 40 into the holder 38 is initially prevented. Once the fan 40 abuts the variable stop, it is optically verified whether the fan 40 is oriented correctly, namely whether its draw side faces away from the heat sink 30. If so, the dome is moved out of the auxiliary opening 80 in the preferred direction 78, and the fan 40 is introduced further into the holder 38 by applying force in the preferred direction 78 until the fan 40 locks to the fan receiver 34. For this purpose, the holder 38 has locking elements not depicted in more detail by which the fan 40 is encompassed on the side facing the opening 42. One end of a connector cable 90 (FIG. 11) of the fan 40 is laid over the edge of the lower part 20 so that it is located outside the lower part 20. In summary, the opening 42 thus in particular forms an opening for installation of the fan 40, that is, a “fan opening.” The auxiliary opening 88, by contrast, in particular forms an “opening for fan inquiry.”

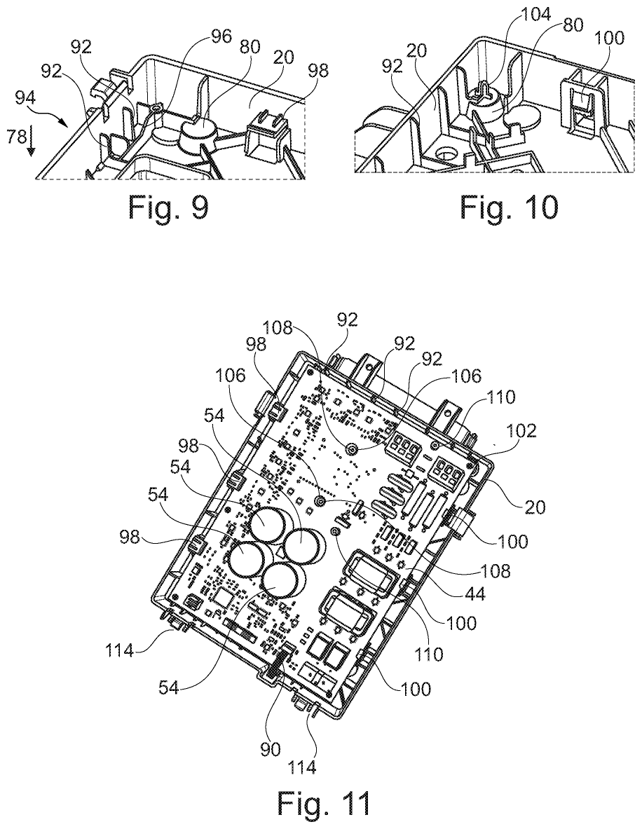

Following this, the first printed circuit board 44 is introduced into the lower part 20. The first printed circuit board 44 is already pre-installed so that the capacitors 54, the power module 48, as well as the other electric and/or electronic structural parts are fastened thereon. For installation, the first printed circuit board 44 is moved to the installation aid 64 in the preferred direction 78, wherein the first printed circuit board 44 is inclined in relation to the bench 66. As a result, an edge of the first printed circuit board 44 initially penetrates the lower part 20. In the process, the two edges of the first printed circuit board 44 perpendicular to this edge slide along multiple guiding fins 92 of a guide 94 of the lower part 20, some of which are shown in a perspective view in FIG. 9. The guiding fins 92 are fastened to an interior of the edge of the lower part 20 and are inclined in relation to the preferred direction 78, wherein the guiding fins 92, at the end facing away from the bench 66, have a decreased extension and are radiused. Thus, on the edge side, the guiding fins 92 act in the manner of a funnel for the first printed circuit board 44, and it is aligned within the lower part 20 in the longitudinal direction.

Therefore, upon further insertion of the first printed circuit board 44 in the preferred direction 78, the front edge of the first printed circuit board 44 is safely moved against two sliding fins 96 of the guide 94, only one of which is shown in FIG. 9. In the region of the first contact with the edge, the sliding fin 96 is disposed in parallel to the bench 66. Now, if further force is exerted onto the first printed circuit board 44 in the preferred direction 78, the edge is moved perpendicular to the preferred direction 78 along the sliding fin 96, which leads to pivoting of the first printed circuit board 44. In the process, the edge is displaced against a portion of the guiding fins 96 inclined counter to the preferred direction 78, which accelerates pivoting. Through the use of the sliding fins 96 as well as the guiding fins 92, the edge is then introduced into three undercuts 98 disposed next to one another each having a slot disposed substantially in parallel to the bench. Thus, through the use of the undercuts 98, the edge of the first printed circuit board 44 is encompassed, prohibiting any further transversal displacement of the edge.

Upon further movement of the first printed circuit board 44 in the preferred direction 78, the edge of the first printed circuit board 44 opposing the undercuts 98 is moved along three locking hooks 100 in the preferred direction 78, one of which is depicted in a perspective view in FIG. 10. When the first printed circuit board 44 is aligned in parallel to the bench 66 due to the force acting in the preferred direction 78, the locking hooks 100 encompass the edge so that detachment of the first printed circuit board 44 from the lower part 20 is no longer possible. In other words, the first printed circuit board 44 is attached to the lower part 20. An end side of the first printed circuit board 44 abuts the bolts 84 so that further movement in the preferred direction 78 is not possible.

During insertion of the first printed circuit board 44, a second centering opening 102 of the first printed circuit board 44, which is formed by a hole in the region of the edge which is encompassed by the locking hooks 100, is assembled on top of a second centering element 104 having a cross-shaped cross section. The second centering element 104 runs parallel to the preferred direction 78, and its free end is integrally injection-molded so that assembling the first printed circuit board 44 on top thereof is facilitated. This involves the second centering element 104 being disposed on the interior of one of the first centering openings 80 so that the first centering element 72 associated with this first centering opening 80 and the second centering element 104 are disposed on a common straight line which is parallel to the preferred direction 78. As a result, comparatively precise alignment of the first printed circuit board 44 in relation to the bench 66 takes place, wherein comparatively large manufacturing tolerances can otherwise be chosen for the lower part 20. Thus, it is ensured that the power module 48, namely the heat dissipator 50, comes into direct contact with the heat sink 30 so that they abut one another. Thus, direct heat conduction between the power module 48 and the heat sink 30 is realized. After inserting the first printed circuit board 44, no consecutive verification or alignment is required as this takes place by inserting the first printed circuit board 44 only. Thermal contacting of the power module 48 with the heat sink 30 is appropriately by or through the further opening 52 which thus forms an opening for the contacting of the power module 48 on the heat sink 30, that is, a “semiconductor module/power module opening.”

After inserting the first printed circuit board 44, installation screws 108 are guided through two installation openings 106 of the first printed circuit board 44 and are inserted into a respective screw receiver of the power module 48, namely of the heat dissipator 50, and there are screwed to the heat sink 30. This involves the diameter of the installation screws 108 being less than the diameter of the installation openings 106 so that the installation screws 108 are located completely below the first printed circuit board 44 in the preferred direction 78 and are in contact with the power module 48 as well as the heat sink 30 only.

Additionally, through the use of further screws 110, the first printed circuit board 44 is screwed to the bolts 84 on which the first printed circuit board 44 rests. The further screws 110, and thus also the heat sink 30, are electrically contacted with traces, not depicted in more detail, of the first printed circuit board 44. Subsequently, the end of the connector cable 90 located outside the lower part 20 is plugged into a corresponding plug on the side of the first printed circuit board 44 facing away from the bench 66 and is thus electrically contacted with the first printed circuit board 44. Thus, the converter 16 has the second production stage depicted in FIG. 11.

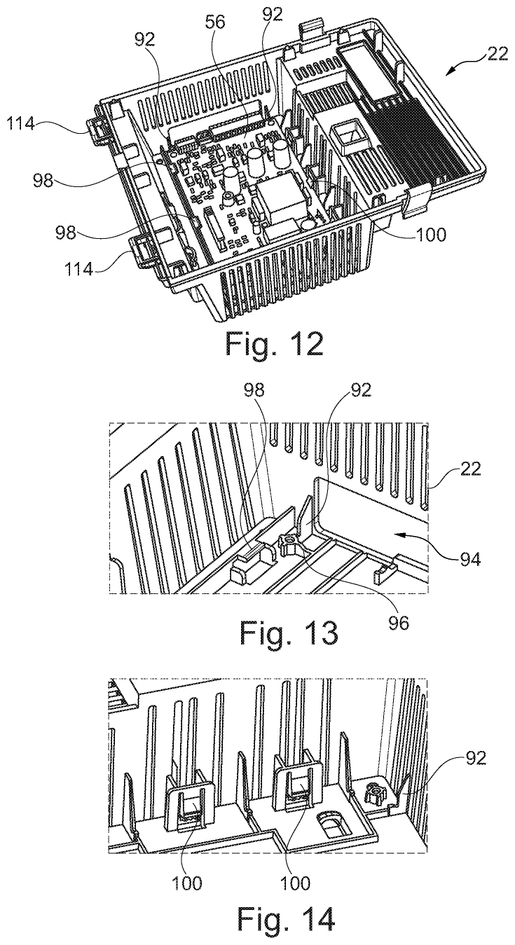

In a subsequent third operation 112, the upper part 22 shown in a perspective view in FIG. 12 is moved to the installation aid 64 in the preferred direction 78 and is laid down on the bench 66. The upper part 22 is positioned perpendicular to the preferred direction 78 next to the lower part 20. The upper part 22 has two hinge parts 114 on its edge side which are formed in the manner of u-shaped lugs. They respectively engage a corresponding hinge part 114 of the lower part 20 which are formed in the manner of an open sleeve or at least have snap-fit hooks or locking hooks. As a result, the two hinges 26 are formed. In summary, the two edge-side hinge parts 114 of the upper part 22 are fastened to a respective one of the edge-side hinge parts 114 of the lower part 20, for which purpose they are locked, so that the two hinges 26 are formed.

Subsequently, the second printed circuit board 56 is inserted into the upper part 22, namely into the protuberance 24, and is attached thereto. For this purpose, the upper part 22 has a guide 94 as well which is formed corresponding to the guide 94 of the lower part 20. Thus, this guide 94 also has two sliding fins 96, multiple guiding fins 92, as well as three undercuts 98, which are partially shown in a perspective view in FIG. 13. Furthermore, the guide 94 also has corresponding locking hooks 100, as depicted in FIG. 14. The procedure and type of attaching the second printed circuit board 56 to the upper part 22 are in correspondence with attaching the first printed circuit board 44 to the lower part 20. Deviating therefrom, only the second centering opening 102 as well as the second centering element 104 are not present here.

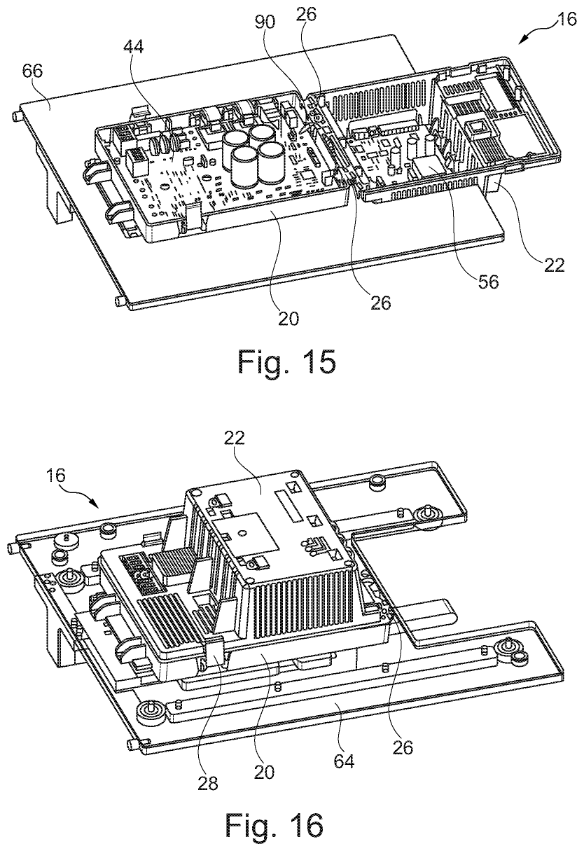

As a result, the converter 16 has the production stage depicted in a perspective view in FIG. 15 in which both the lower part 20 and the upper part 22 rest on the bench 66, and wherein the first printed circuit board 44 is disposed within the lower part 20 and the second printed circuit board 56 is disposed within the upper part 22, and wherein the upper part 22 and the lower part 20 are fastened to one another by the hinges 26.

Following this, a fourth operation 114 is performed. Therein, the flat cable 58 is moved to the installation aid 64 in the preferred direction 78 and is plugged into corresponding plug receivers of the first printed circuit board 44 and of the second printed circuit board 56 in the preferred direction 78. Following this, the upper part 22 is folded onto the lower part 20 by the hinges 26 and there is secured by the snap-fit hooks 28, as depicted in FIG. 16. Following this, the converter 16 is finished, and it is removed from the installation aid 64 depicted transparently in FIG. 16.

In summary, for installation of the converter 16, all of the components, such as the heat sink 30, the individual constituents of the housing 18, and the electronics 46 having the two printed circuit boards 44, 46, are moved to the installation aid 64, which is not moved or is only moved transversally during the method 62, in the preferred direction 78 only. At the installation aid 64, the components are assembled and joined together in the preferred direction 78. Thus, the individual components are fastened to one another in the preferred direction 78 only.

The invention is not limited to the exemplary embodiment described above. Rather, other variations of the invention may also be derived therefrom by a person/persons skilled in the art without departing from the subject matter of the invention. In particular, all of the individual features described in conjunction with the exemplary embodiment are additionally combinable with one another in other ways without departing from the subject matter of the invention.

The following is a summary list of reference numerals and the corresponding structure used in the above description of the invention:
2 Heat pump
4 Refrigerant loop
6 Compressor
8 First heat exchanger
10 Expansion valve
12 Second heat exchanger
14 Electric motor
16 Converter
18 Housing
20 Lower part
22 Upper part
24 Protuberance
26 Hinge
28 Snap-fit hook
30 Heat sink
32 Cooling fin
34 Fan receiver
36 Diffuser
38 Holder
40 Fan
42 Opening
44 First printed circuit board
46 Electronics
48 Power module
50 Heat dissipator
52 Further opening
54 Capacitor
56 Second printed circuit board
58 Flat cable
60 Slot
62 Method
64 Installation aid
66 Bench
68 Receiver
70 Second receiver
72 First centering element
74 Installation rail
76 First operation
78 Preferred direction
80 First centering opening
82 Screw
84 Bolt
86 Second operation
88 Auxiliary opening
90 Connector cable
92 Guiding fin
94 Guide
96 Sliding fin
98 Undercut
100 Locking hook
102 Second centering opening
104 Second centering element
106 Installation opening
108 Installation screw
110 Further screw
112 Third operation
114 Fourth operation

1. A method for producing a converter for a heat pump on an installation aid, the method comprising:
providing the converter, the converter having a heat sink, a housing with an upper part and a lower part, and electronics;
moving each of the heat sink, the housing and the electronics to the installation aid one after another in a common preferred direction and assembling and joining the heat sink, the housing and the electronics together in the preferred direction on the installation aid.

2. The method according to claim 1, which further comprises initially inserting the heat sink into a receiver of the installation aid, and subsequently assembling the lower part onto the heat sink and attaching the lower part to the heat sink.

3. The method according to claim 2, which further comprises initially inserting a fan receiver into a second receiver of the installation aid in the preferred direction and positioning the fan receiver perpendicular to the preferred direction next to the heat sink, and subsequently assembling the lower part onto the fan receiver with an opening of the fan receiver reaching into the lower part.

4. The method according to claim 3, which further comprises inserting a fan through the opening into the fan receiver in the preferred direction.

5. The method according to claim 2, which further comprises fastening a power module to a first printed circuit board of the electronics, and inserting the first printed circuit board into the lower part with the power module abutting the heat sink.

6. The method according to claim 5, which further comprises attaching the first printed circuit board to the lower part, and inserting an installation screw through an installation opening of the first printed circuit board into a screw receiver of the power module in the preferred direction and screwing the power module to the heat sink.

7. The method according to claim 5, which further comprises assembling a first centering opening of the lower part onto a first centering element of the installation aid, and assembling a second centering opening of the first printed circuit board onto a second centering element of the lower part, the two centering elements being disposed along a common straight line parallel to the preferred direction.

8. The method according to claim 1, which further comprises positioning the upper part perpendicular to the preferred direction next to the lower part, and fastening an edge-side hinge part of the lower part to an edge-side hinge part of the upper part.

9. The method according to claim 8, which further comprises inserting a second printed circuit board into the upper part in the preferred direction, and attaching the second printed circuit board to the upper part.

10. A converter for a heat pump, the converter comprising a heat sink, a housing and electronics being fastened to one another in a preferred direction only.

11. The converter according to claim 10, wherein the heat sink is rigidly fastened to the electronics to form an assembly, and the assembly is floatingly supported on the housing.
